(19) United States
(12) Patent Application Publication
(10) Pub. No.: US 2026/0237444 A1
(43) Pub. Date: Aug. 13, 2026

(54) ACCESS VOLTAGE CORRECTION

(71) Applicant: Micron Technology, Inc., Boise, ID (US)

(72) Inventors: Zhaohang Yu, Shanghai (CN); Chun Sum Yeung, San Jose, CA (US); Chen Xu, Shanghai (CN)

(21) Appl. No.: 19/455,621

(22) Filed: Jan. 21, 2026

Related U.S. Application Data
(60) Provisional application No. 63/755,473, filed on Feb. 7, 2025.

(51) Int. Cl. G11C 16/26; G11C 16/16; G11C 16/34

(52) U.S. Cl. CPC G11C 16/26; G11C 16/16; G11C 16/349

(57) ABSTRACT

Methods, systems, and devices for access voltage correction are described. An offset table may be selected from among a plurality of offset tables in accordance with a quantity of program and erase cycles associated with the memory system. After selecting the offset table and in response to a command to read data from a block of the memory system, data may be read from the block. Reading the data from the block may include applying an offset to a read voltage, where the offset may be associated with the block in the offset table, and where the offset may be associated with a duration since the block was last programmed.

### CROSS REFERENCE

The present Application for Patent claims priority to U.S. Patent Application No. 63/755,473 by Yu et al., entitled “ACCESS VOLTAGE CORRECTION,” filed Feb. 7, 2025, which is assigned to the assignee hereof, and which is expressly incorporated by reference in its entirety herein.

### TECHNICAL FIELD

The following relates to one or more systems for memory, including access voltage correction.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports access voltage correction in accordance with examples as disclosed herein.

FIG. 2 shows an example of a sub system that supports access voltage correction in accordance with examples as disclosed herein.

FIG. 3 shows an example of a set of operations for access voltage correction in accordance with examples as disclosed herein.

FIG. 4 shows an example of a diagram for access voltage correction in accordance with examples as disclosed herein.

FIG. 5 shows a block diagram of a memory system that supports access voltage correction in accordance with examples as disclosed herein.

FIG. 6 shows a flowchart illustrating a method or methods that support access voltage correction in accordance with examples as disclosed herein.

### DETAILED DESCRIPTION

Charge stored in a memory cell (which may correspond to a logic state of the memory cell) may be lost over time in what may be referred to as the charge loss effect. Over time, the charge loss effect may cause a block of memory cells to output data (in response to a read command) with a bit error rate that is greater than a threshold bit error rate. In some examples, techniques for mitigating the charge loss effect may be used that involve applying read level offsets to read voltages used to read a block of memory cells based on a duration since the block of memory cells was last programmed.

However, current techniques for mitigating the charge loss effect may not accommodate for the change in the charge loss effect that occurs as a memory system ages (e.g., as the number of PECs experienced by the memory system increased). For example, for current techniques, the same read level offsets may be applied to the blocks of memory cells throughout the life of the memory system and regardless of the quantity of PECs applied to the blocks of memory cells. Thus, at higher PEC levels, current techniques for mitigating the charge loss effect may fail to allow the blocks of memory cells to continue to store data with a threshold bit error rate for a threshold duration. Similarly, in some examples, current techniques for mitigating the charge loss effect may perform sub-optimally through a significant portion of the life of the memory system. Thus, implementations (e.g., methods, systems, apparatuses, techniques, configurations, components) that support adapting to the changing charge loss effect based on applied PECs may be desired.

To adapt to the changing charge loss effect based on applied PECs, techniques for adapting read level offsets applied to memory cells based on a quantity of PECs applied to the memory cells may be implemented. In some examples, multiple offset tables may be stored, where respective offset tables of the multiple offset tables may indicate a set of read level offsets to apply to the memory cells based on respective PEC conditions (e.g., at specific PEC values, within respective PEC ranges, etc.).

In addition to applicability in memory systems as described herein, techniques for access voltage correction may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by tailoring read offset voltages applied to memory cells based on current PEC conditions, which may improve a reliability of data stored in the memory cells (e.g., by allowing data to be successfully read from the memory cells for a longer period of time since a last programming), among other benefits.

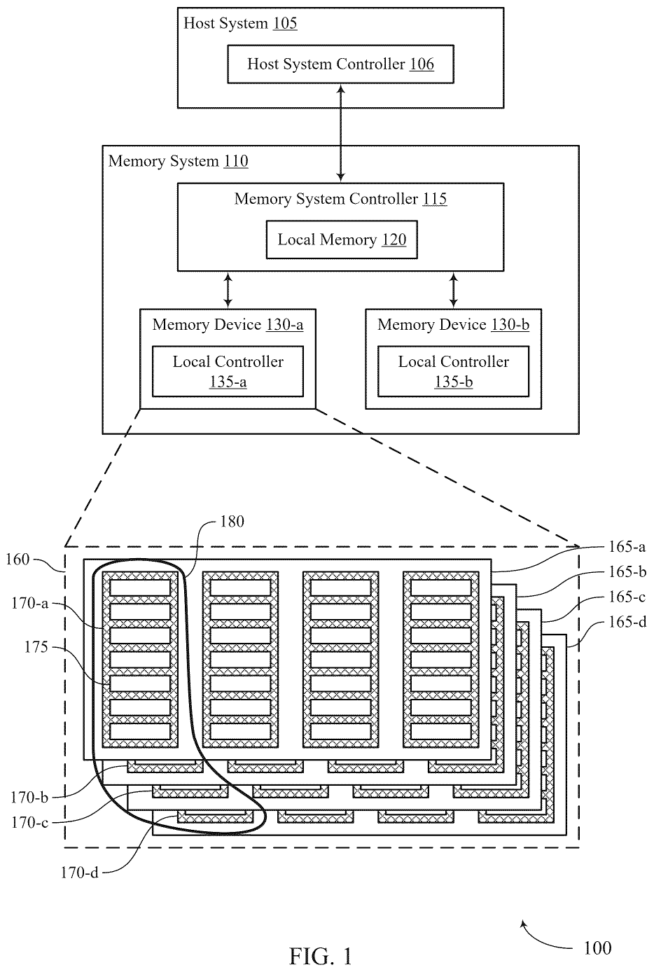

FIG. 1 shows an example of a system 100 that supports access voltage correction in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

A memory system may include memory cells, which may be configured to store data (e.g., in a binary format). In some examples, the memory cells include one or more of the following: single-level cells (SLCs) that are capable of maintaining two states and representing a bit of information; bi-level cells (BLCs) (which may also be referred to as multi-level cells (MLCs)) that are capable of maintaining four states and representing up to two bits of information; tri-level cells (TLCs) that are capable of maintaining eight states and representing up to three bits of information; quad-level cells (QLCs) that are capable of maintaining sixteen states and representing up to four bits of information, and so on.

In some examples, the memory cells included in a memory system are all of a same type (e.g., are all QLCs). In some examples, higher-levels cells (e.g., MLCs, TLCs, or QLCs) may be programmed using multiple programming techniques (e.g., single-level, bi-level, or tri-level techniques)—e.g., to support faster programming operations, more reliable programming operations, etc. For example, a QLC may be programmed using a SLC programming technique. In some examples, one or more portions of the memory cells in a memory system may be configured to be programmed using different techniques—e.g., for a set of QLCs, a first portion of the QLCs may be configured to be programmed using SLC techniques (e.g., to provide a low-latency cache memory portion) and a second portion of the QLCs may be configured to be programming using QLC techniques (e.g., to provide a high-density memory portion).

The state of a memory cell may degrade over time. For example, the state of a memory cell degrades over time as charge stored in a gate of the memory cell escapes—e.g., as a result of leakage, thermal emission, tunneling, etc. The loss of charge may be referred to as slow charge loss (SCL). In some examples, the longer it has been since a memory cell has been programmed, the larger the effect slow charge loss may have on (e.g., the more charge may be lost from) that memory cell.

Certain types of memory cells (e.g., SLCs and BLCs) may have read window budgets (RWBs) that render techniques for mitigating slow charge loss unnecessary. Such types of memory cells may store data with a threshold bit error rate for at least a threshold duration (e.g., years, tens of years) since the memory cells were programmed regardless of whether techniques for mitigating slow charge loss are applied. Other types of memory cells (e.g., higher-level memory cells, such as TLCs and QLCs) may have smaller read window budgets. For such types of memory cells, techniques may be implemented to mitigate the effect of slow charge loss. In some examples, these techniques may allow the memory cells to store data with a threshold bit error rate for increased durations (e.g., for at least the threshold duration) since the memory cells were programmed. For example, a block family error avoidance (BFEA) algorithm may be used to mitigate the slow charge loss effect on blocks (e.g., superblocks) or on pages within a block by accessing memory cells by applying read level offsets to read voltages, where the applied read level offsets may be based on a duration since the memory cells were last programmed.

In some examples, the charge loss effect on a memory cell may change (e.g., increase) as the program and erase cycles (PECs) for the memory cell increase. Moreover, current techniques for mitigating the charge loss effect may not accommodate for the change in the charge loss effect caused by a change in PECs—e.g., the same read level offsets may be applied to the blocks of memory cells throughout the life of the memory system and regardless of the quantity of PECs applied to the blocks of memory cells. Thus, at higher PEC levels, current techniques for mitigating the charge loss effect may fail to allow the blocks of memory cells to continue to store data with a threshold bit error rate for the threshold duration. Similarly, in some examples, current techniques for mitigating the charge loss effect may perform sub-optimally through much of the life of the memory system. For example, the read level offsets may work optimally when the PECs applied to the blocks of memory cells are within a particular range and sub optimally when the PECs applied to the blocks of memory cells are outside the particular range—e.g., the read level offsets may be too strong for low PEC conditions and not strong enough for high PEC conditions. Thus, implementations (e.g., methods, systems, apparatuses, techniques, configurations, components) that support adapting to the changing charge loss effect based on applied PECs may be desired.

To adapt to the changing charge loss effect based on applied PECs, techniques for adapting read level offsets applied to memory cells based on a quantity of PECs applied to the memory cells may be implemented. In some examples, multiple offset tables may be stored, where respective offset tables of the multiple offset tables may indicate a set of read level offsets to apply to the memory cells based on respective PEC conditions (e.g., at specific PEC values, within respective PEC ranges, etc.).

In some examples, a memory system (e.g., the memory system 110) may select an offset table from multiple offset tables available for accounting for charge loss effect based on a quantity of PECs applied to a memory system (e.g., on an averaged system-level basis). In some examples, the offset table includes a set of entries for a set of blocks of memory cells, where each entry may indicate an offset to apply to a read voltage used to access a respective block of memory cells. The offset table may be associated with a first range of PECs (e.g., 10 to 20 PECs). The other offset tables may similarly be associated with respective ranges of PECs. In some examples, the quantity of PECs applied to the blocks of memory cells in the memory system are maintained at similar levels (e.g., using a wear leveling technique) such that a PEC level determined for one block of memory cells may provide a good estimate (e.g., may be within a threshold amount from) of a PEC level for the other blocks of memory cells in the memory system.

After selecting the offset table, a command to read data from a block of memory cells in the memory system may be received at the memory system. The memory system may initiate a read operation for the block of memory cells in response to the command. As part of the read operation, the memory system may apply an offset to a read voltage for reading the block of memory cells, where the offset may be associated with the block of memory cells in the offset table, and where the offset may be associated with a duration since the block was last programmed. For example, the offset may increase as the duration since the block was last programmed increases.

By selecting an offset from among multiple available offset tables based on a PEC level of a memory system, read offsets that are tailored to PEC level of the memory system may be used. As such, a reliability of data stored within the blocks of memory cells may be retained for an increased duration (e.g., relative to if a single offset table that disregarded PEC levels were used).

The system 100 may include any quantity of non-transitory computer readable media that support access voltage correction. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

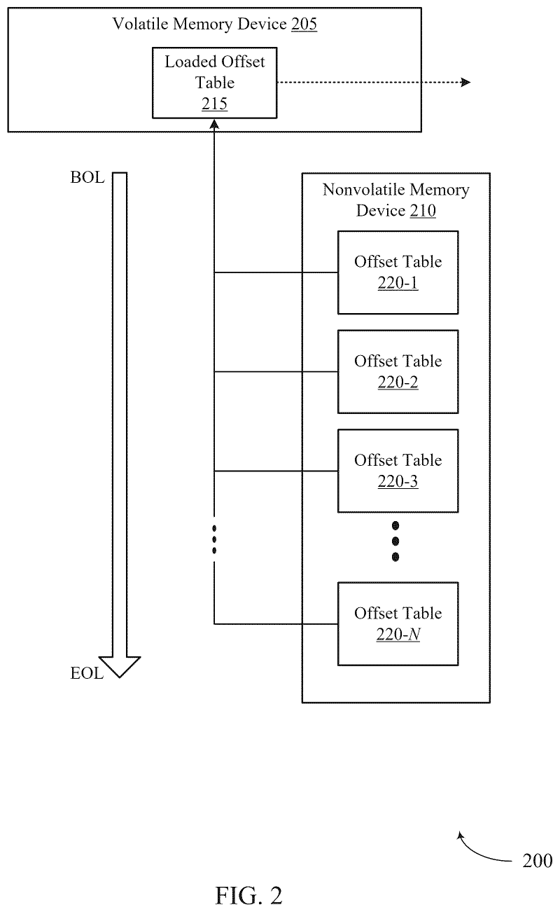

FIG. 2 shows an example of a subsystem that supports access voltage correction in accordance with examples as disclosed herein.

The subsystem 200 may include the volatile memory device 205 and the nonvolatile memory device 210. In some example, multiple offset tables (the first offset table 220-1 through the Nth offset table 220-N) may be stored within the nonvolatile memory device 210. In some examples, multiple (e.g., four) copies of each offset table may be stored within the nonvolatile memory device 210 (e.g., for error management purposes). The offset tables may be associated with different PEC levels being applied to a memory system. For example, the first offset table 220-1 may be associated with a first PEC level (e.g., 0) or a first PEC level range (e.g., 0 to 10 PECs), the second offset table 220-2 may be associated with a second PEC level (e.g., 1) or a second PEC level range (e.g., 11 to 20 PECs), and so on. In some examples, the initial offset tables may be associated with a beginning of life (BOL) for the memory system (which may correspond to a low PEC range), the intermediary offset tables may be associated with a middle of life (MOL) for the memory system (which may correspond to an intermediate PEC range), and the ending offset tables may be associated with an end of life (EOL) for the memory system (which may correspond to a high PEC range).

In some examples, one or more of the offset tables may be loaded into the volatile memory device 205. In some examples, the offset table loaded into the volatile memory device 205 (e.g., the loaded offset table 215) is loaded into the volatile memory device 205 based on the memory system (e.g., a controller at the memory system) determining that a PEC level for the memory system is different than a PEC level, or outside a PEC range, associated with the previously loaded offset table. Based on determining that the PEC level for the memory system is different than the PEC level, or outside the PEC range, associated with the previously loaded offset table, the memory system may identify an offset table associated with a PEC level that matches, or a PEC range that includes, the PEC level for the memory system (e.g., the loaded offset table 215) and may load the identified offset table into the volatile memory device 205. In some examples, the memory system causes the previously loaded offset table to be removed from the volatile memory device 205—e.g., after the loaded offset table 215 is successfully retrieved from the nonvolatile memory device 210 and loaded into the volatile memory device 205.

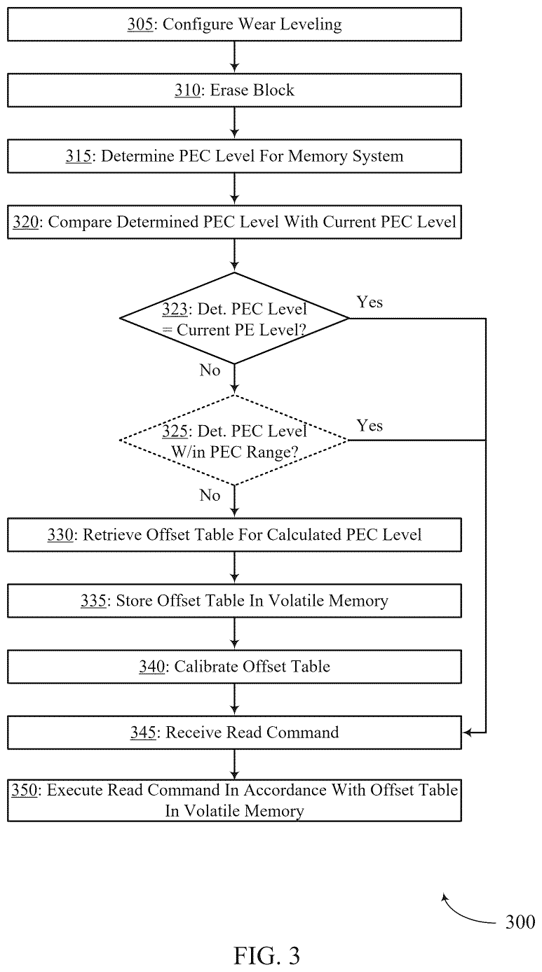

FIG. 3 shows an example of a set of operations for access voltage correction in accordance with examples as disclosed herein.

The flowchart 300 may be performed by a memory system, which may be an example of a memory system 110 described herein. In some examples, the flowchart 300 shows an example set of operations performed to support access voltage correction. For example, the flowchart 300 may include operations for loading and using offset tables based on PEC conditions for a memory system.

At 305, a wear leveling procedure may be configured at the memory system. The wear leveling procedure may cause a consistent quantity of PECs to be applied across the blocks within the memory system—e.g., by strategically selecting blocks for subsequent programming operations based on PEC levels. In some examples, the memory system may maintain a record of the quantity of PECs applied to the blocks in the memory system.

At 310, a block in the memory system may be erased—e.g., during a garbage collection operation.

At 315, a PEC level for the memory system may be determined based on erasing the block. In some examples, a PEC level for the block may be determined after erasing the block. In some cases, the PEC level for the block may be incremented after the block is erased, and the PEC level determined for the block may be equal to the incremented PEC level. Based on determining the PEC level for the block, the memory system may determine that the PEC level for the memory system is equivalent to the PEC level for the block—e.g., based on wear leveling being configured.

At 320, the determined PEC level for the memory system may be compared with the current PEC level for the memory system (e.g., the current PEC level for the memory system used for identifying an offset table for addressing the charge loss effect). If the determined PEC level is different than (e.g., greater than) the current PEC level, the current PEC level may be updated to be equivalent to the determined PEC level.

At 323, whether the determined PEC level is different than the current PEC level may be determined. In some examples, if the determined PEC level for the block is the same as the current PEC level for the memory system, the memory system may refrain from loading a new offset table and wait for a read command to be received.

In some examples, if the determined PEC level for the block is different than the current PEC level for the memory system, the memory system may proceed directly to retrieving the offset table matching the determined PEC level for the block (e.g., if there are offset tables for each PEC level). In other examples, if the determined PEC level for the block is different than the current PEC level for the memory system, the memory system may proceed to determine whether the determined PEC level of the memory system remains within a PEC range associated with the currently loaded offset table.

At 325, whether the updated current PEC level for the memory system is within a PEC range associated with an offset table currently loaded in volatile memory may be determined—e.g., based on the PEC level of the block being determined as being different than the current PEC level of the memory system.

In some examples, if the determined PEC level (e.g., 11) for the memory system is within the PEC range (e.g., 11 through 20) of the currently loaded offset table, the memory system may refrain from loading a new offset table and wait for a read command to be received. In some examples, the PEC range may encompass a single value (e.g., 11) and offset tables may exist for each PEC value. In some examples, the currently loaded offset table may have the following structure.

Offset Table (11 through 20 PECs | 11 PEC |)

| | | Read | Read | | Read |
|---|---|---|---|---|---|
| Block Family (BF) / | | Retry | Retry | | Retry |
| Virtual Block (VB) # | Temp. | Die 0 | Die 1 | . . . | Die 7 |
| 0 | 45 | 3 | 3 | . . . | 3 |
| 1 | 70 | 2 | 2 | . . . | 2 |
| . . . | . . . | . . . | . . . | . . . | . . . |
| 10 | 50 | 1 | 1 | . . . | 1 |
| 11 | 60 | 0 | 0 | . . . | 0 |
| . . . | . . . | . . . | . . . | . . . | . . . |
| 719 | −1 | −1 | −1 | . . . | −1 |
| 720 | −1 | −1 | −1 | . . . | −1 |

The values in the “Read Retry” columns may correspond to read voltage offsets, with higher numbers being associated with higher offsets. The “−1” values may indicate that the corresponding blocks have not yet been programmed (e.g., since a last erase operation). In some examples, the offsets in the table may be calibrated (e.g., periodically, or in response to a trigger)—e.g., the offsets for previously programmed blocks may increase as the duration since the last programming increased, offsets for newly programming blocks may be added, etc.

If the determined PEC level (e.g., 21) for the memory system is outside the PEC range associated with the currently loaded offset table, a procedure for loading a new offset table may be performed.

At 330, a new offset table associated with the current PEC level may be retrieved from nonvolatile memory. In some examples, the new offset table is associated with a PEC range (e.g., 21 through 30) that includes the current PEC level. In other examples, the new offset table is associated with a PEC value (e.g., 12) that matches the current PEC level.

In some examples, four copies of the new offset table are stored in the volatile memory. In such cases, the memory system may read subsequent copies of the new offset table if a retrieved copy of the offset table is corrupted. In some examples, if a copy of the offset table is unable to be read, the memory system may attempt to retrieve and use a second offset table associated with the following PEC range. In some examples, if the memory system is unable to read the second offset table associated with the following PEC range, the memory system may retain the currently loaded offset table.

At 335, the new offset table retrieved from the nonvolatile memory may be loaded into volatile memory. In some examples, the previously loaded offset table may be removed from memory once the new offset table is successfully loaded into volatile memory. In some examples, the newly loaded offset table may have the following structure.

Offset Table (21 through 30 PECs | 12 PEC)

| | | Read | Read | | Read |
|---|---|---|---|---|---|
| Block Family (BF) / | | Retry | Retry | | Retry |
| Virtual Block (VB) # | Temp. | Die 0 | Die 1 | . . . | Die 7 |
| 0 | 45 | 5 | 5 | . . . | 5 |
| 1 | 70 | 4 | 4 | . . . | 4 |
| . . . | . . . | . . . | . . . | . . . | . . . |
| 10 | 50 | 3 | 3 | . . . | 3 |
| 11 | 60 | 1 | 1 | . . . | 1 |
| . . . | . . . | . . . | . . . | . . . | . . . |
| 719 | −1 | −1 | −1 | . . . | −1 |
| 720 | −1 | −1 | −1 | . . . | −1 |

In some examples, for a same duration since last programming, the offsets for a block (e.g., block 10) using the new offset table may be different than if the previous offset table were loaded—e.g., one or more of the offsets in the new offset table may be higher to account for a stronger charge loss effect at the higher PEC level.

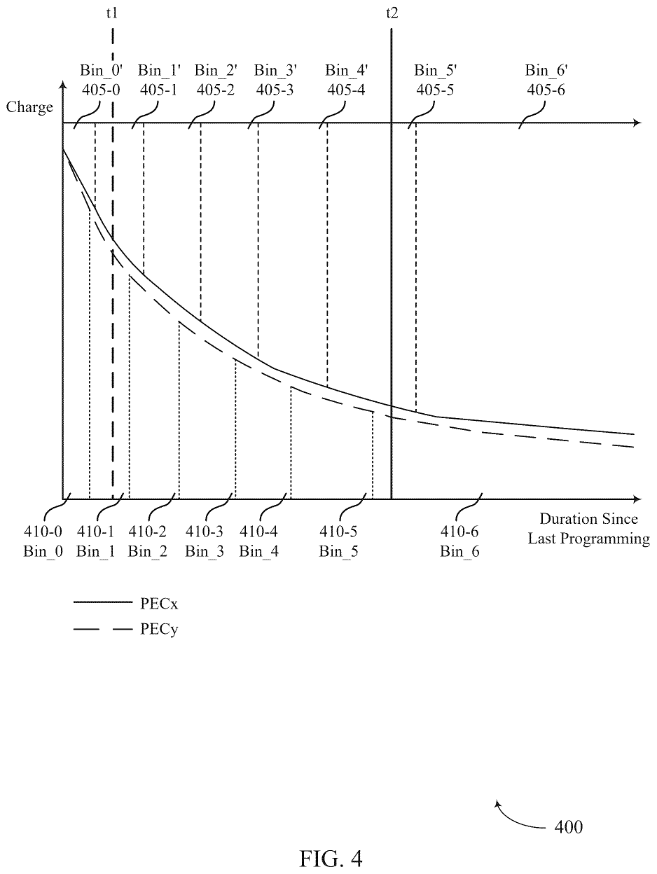

At 340, the new offset table may be calibrated (e.g., periodically or in response to an event, such as a block erase). In some examples, the offsets for the blocks may be updated based on an updated duration since the blocks were last programmed. In some examples, the offsets for the new offset table may be calculated differently than the offsets for the previously loaded offset table—e.g., based on updated charge loss effect characteristics, which are described herein, including with reference to FIG. 4.

At 345, a read command may be received. The read command may request data to be read from an address associated with a block. In some examples, the new offset table has been updated as follows when the read command is received.

Offset Table (21 through 30 PECs)

| | | Read | Read | | Read |
|---|---|---|---|---|---|
| Block Family (BF) / | | Retry | Retry | | Retry |
| Virtual Block (VB) # | Temp. | Die 0 | Die 1 | . . . | Die 7 |
| 0 | 45 | 6 | 6 | . . . | 6 |
| 1 | 70 | 6 | 6 | . . . | 6 |
| . . . | . . . | . . . | . . . | . . . | . . . |
| 10 | 50 | 4 | 4 | . . . | 4 |
| 11 | 60 | 3 | 3 | . . . | 3 |
| 12 | 55 | 1 | 1 | . . . | 1 |
| 13 | 60 | 0 | 0 | . . . | 0 |
| . . . | . . . | . . . | . . . | . . . | . . . |
| 719 | −1 | −1 | −1 | . . . | −1 |
| 720 | −1 | −1 | −1 | . . . | −1 |

At 350, the read command may be executed by the memory system. As part of executing the read command, the memory system may apply a read voltage to the block (e.g., block 10). The memory system may additionally apply a read offset voltage (e.g., an offset voltage corresponding to a level 4 offset) to the read voltage based on the offset stored for the block in the new offset table.

Aspects of the flowchart 300 may be implemented by a controller, among other components. Additionally, or alternatively, aspects of the flowchart 300 may be implemented as instructions stored in memory (e.g., firmware stored in a memory coupled with a controller). For example, the instructions, when executed by a controller, may cause the controller to perform the operations of the flowchart 300.

One or more of the operations described in the flowchart 300 may be performed earlier or later, omitted, replaced, supplemented, or combined with another operation. Also, additional operations described herein may replace, supplement or be combined with one or more of the operations described in the flowchart 300.

FIG. 4 shows an example of a diagram that supports access voltage correction in accordance with examples as disclosed herein.

The diagram 400 depicts a change in the charge loss effect on a block at different PEC levels. In the diagram 400, the solid and dotted curves depict a loss in charge for a block as a function of a duration since a last programming for the block. The diagram 400 further depicts bins associated with different durations since last programming and different ranges of stored charge at the block.

For example, for a first PEC level (depicted by the solid curve and referenced as PECx), the diagram 400 depicts the zeroth bin 405-0 through the sixth bin 405-6, and for a second PEC level (depicted by the dashed curve and referenced as PECy), the diagram 400 depicts the zeroth bin 410-0 through the sixth bin 410-6. In some examples, the first PEC level may be associated with a first range of PECs (e.g., 0 through 10), and the second PEC level may be associated with a second range of PECs (e.g., 11 through 20). In some examples, the first PEC level may be associated with a first PEC level (e.g., 10), and the second PEC level may be associated with a second PEC level (e.g., 11).

In some examples, for the first PEC level, a read voltage offset associated with offset 0 (e.g., no read voltage offset) may be applied to blocks that are associated with a first duration since last programming (e.g., and thereby associated with an amount of stored charge corresponding to the portion of the solid curve within the zeroth bin 405-0). Also, for the first PEC level, a read voltage offset associated with offset 1 (e.g., a first read voltage offset) may be applied to blocks that are associated with a second duration since last programming (e.g., and thereby associated with an amount of stored charge corresponding to the portion of the solid curve within the first bin 405-1), and so on.

In some examples, for the second PEC level, a read voltage offset associated with offset 0 (e.g., no read voltage offset) may be applied to blocks that are associated with a third duration since last programming (e.g., and thereby associated with an amount of stored charge corresponding to the portion of the dashed curve within the zeroth bin 410-0). The third duration may be shorter than the first duration associated with the zeroth bin 405-0. Also, for the second PEC level, a read voltage offset associated with offset 1 (e.g., the first read voltage offset) may be applied to blocks that are associated with a fourth duration since last programming (e.g., and thereby associated with an amount of stored charge corresponding to the portion of the dashed curve within the first bin 410-1), and so on. The fourth duration may be shorter than the second duration associated with the first bin 410-1.

As illustrated in FIG. 4, in some examples, for a block associated with a same duration since last programming (e.g., illustrated by the solid vertical line at t₂), different offsets may be applied based on whether the memory system is associated with the first PEC level or the second PEC level. For example, for the first PEC level, the block may fall within the fifth bin 405-5 (which may be associated with a fifth read voltage offset), but for the second PEC level, the block may fall within the sixth bin 410-6 (which may be associated with a larger sixth read voltage offset).

In some examples, for a block associated with a same duration since last programming (illustrated by the dashed vertical line at t₁), the same offsets may be applied regardless of whether the memory system is associated with the first PEC level or the second PEC level. For example, for the first PEC level, the block may fall within the first bin 405-1 (which may be associated with a first read voltage offset), and for the second PEC level, the block may fall within the first bin 410-1 (which may be associated with the same first read voltage offset).

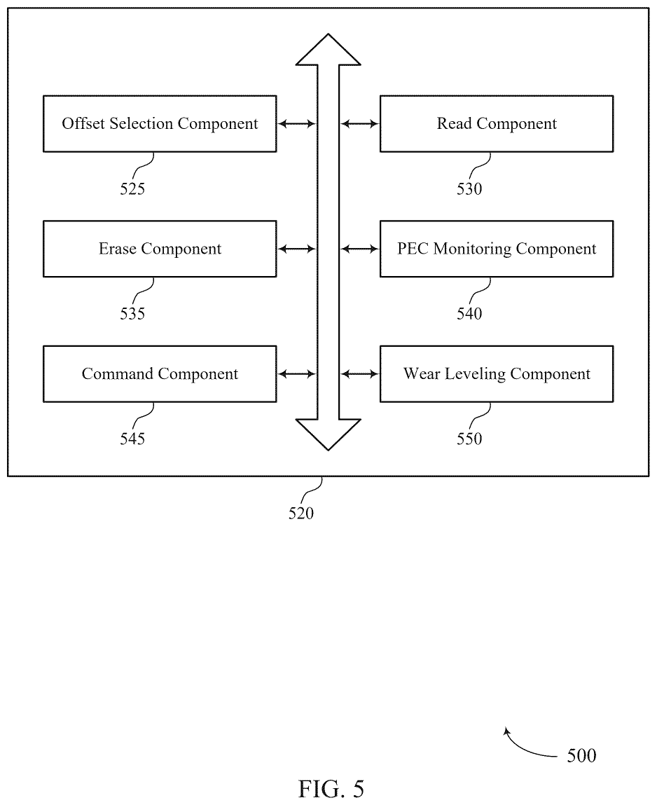

FIG. 5 shows a block diagram 500 of a memory system 520 that supports access voltage correction in accordance with examples as disclosed herein. The memory system 520 may be an example of aspects of a memory system as described with reference to FIGS. 1 through 4. The memory system 520, or various components thereof, may be an example of means for performing various aspects of access voltage correction as described herein. For example, the memory system 520 may include an offset selection component 525, a read component 530, an erase component 535, a PEC monitoring component 540, a command component 545, a wear leveling component 550, or any combination thereof. Each of these components, or components of subcomponents thereof (e.g., one or more processors, one or more memories), may communicate, directly or indirectly, with one another (e.g., via one or more buses).

The offset selection component 525 may be configured as or otherwise support a means for selecting, from among a plurality of offset tables, an offset table in accordance with a quantity of program and erase cycles associated with the memory system, where each of the plurality of offset tables indicates a respective set of offsets for read voltages associated with the memory system. The read component 530 may be configured as or otherwise support a means for reading, after selecting the offset table and in association with a command to read data from a block of the memory system, data from the block, where reading the data from the block includes applying an offset to a read voltage, where the offset table associates the offset with the block, and where a size of the offset is in accordance with a duration since the block was last programmed.

In some examples, the erase component 535 may be configured as or otherwise support a means for erasing, prior to selecting the offset table, the block or a second block in the memory system. In some examples, the PEC monitoring component 540 may be configured as or otherwise support a means for determining, in accordance with erasing the block or the second block, a second quantity of program and erase cycles for the erased block. In some examples, the PEC monitoring component 540 may be configured as or otherwise support a means for updating the quantity of program and erase cycles associated with the memory system to match the second quantity of program and erase cycles for the erased block.

In some examples, the offset selection component 525 may be configured as or otherwise support a means for comparing, in accordance with determining the second quantity of program and erase cycles for the erased block, the determined second quantity of program and erase cycles with a current quantity of program and erase cycles associated with the memory system, where the quantity of program and erase cycles associated with the memory system is updated as a result of the determined second quantity of program and erase cycles being greater than the current quantity of program and erase cycles associated with the memory system.

In some examples, the offset selection component 525 may be configured as or otherwise support a means for retrieving, in accordance with updating the quantity of program and erase cycles associated with the memory system, the offset table from a nonvolatile memory of the memory system, the offset table being associated with a range of program and erase cycles including the updated quantity of program and erase cycles associated with the memory system. In some examples, the offset selection component 525 may be configured as or otherwise support a means for loading, in accordance with retrieving the offset table, the offset table into a volatile memory of the memory system.

In some examples, the offset selection component 525 may be configured as or otherwise support a means for evicting, in accordance with loading the offset table into the volatile memory, a second offset table from the volatile memory, the second offset table being associated with a second range of program and erase cycles excluding the updated quantity of program and erase cycles associated with the memory system.

In some examples, the offset table includes a plurality of entries, respective entries of the plurality of entries including respective offsets to apply to respective blocks of the memory system in accordance with respective times since the respective blocks were programmed. In some examples, the method further includes calibrating, after loading the offset table in the volatile memory, the respective offsets in accordance with a calibration schedule.

In some examples, the offset selection component 525 may be configured as or otherwise support a means for selecting, prior to selecting the offset table, from among the plurality of offset tables, a second offset table in accordance with a second quantity of program and erase cycles associated with the memory system. In some examples, the read component 530 may be configured as or otherwise support a means for reading, after selecting the second offset table and in association with a second command to read data from the block of the memory system, data from the block, where reading the data from the block includes applying a second offset to the read voltage, the second offset table associating the second offset with the block.

In some examples, the read component 530 may be configured as or otherwise support a means for applying the second offset to the read voltage when the block is read in association with the second command in accordance with a second time since programming the block being within a time range. In some examples, the read component 530 may be configured as or otherwise support a means for applying the offset to the read voltage when the block is read in association with the command in accordance with a time since programming the block being within the time range, the time being different than the second time.

In some examples, the wear leveling component 550 may be configured as or otherwise support a means for configuring, prior to erasing the second block, a wear leveling task at the memory system, where the quantity of program and erase cycles associated with the memory system is updated to match the quantity of program and erase cycles for the second block in accordance with the wear leveling task being configured.

In some examples, each of the plurality of offset tables is associated with a respective range of program and erase cycles.

In some examples, for each offset table in the plurality of offset tables, offsets in the respective set of offsets are in accordance with respective times since respective blocks of the memory system were programmed.

In some examples, for a first duration since the block was programmed, a first offset associated with the block in the offset table is different than a second offset associated with the block in a second offset table, wherein the offset table is associated with a first range of program and erase cycles. In some examples, the second offset table is associated with a second range of program and erase cycles.

In some examples, the command component 545 may be configured as or otherwise support a means for receiving, after selecting the offset table, the command to read the data from the block of the memory system.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

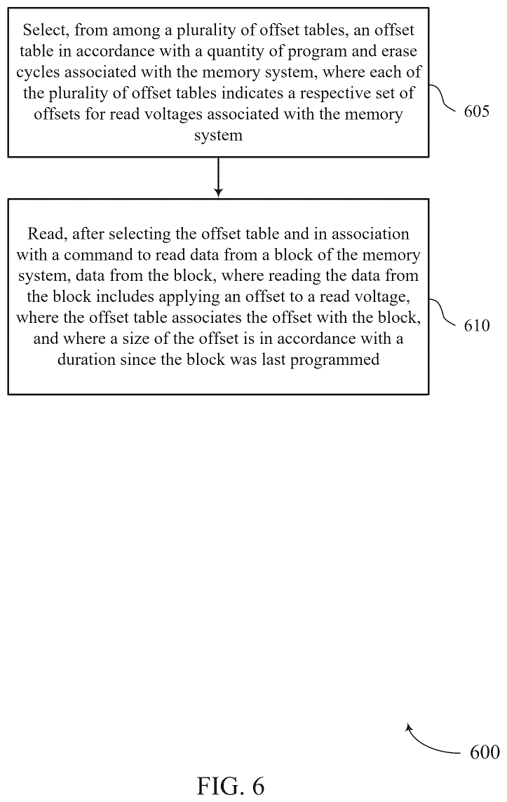

FIG. 6 shows a flowchart illustrating a method 600 that supports access voltage correction in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include selecting, from among a plurality of offset tables, an offset table in accordance with a quantity of program and erase cycles associated with the memory system, where each of the plurality of offset tables indicates a respective set of offsets for read voltages associated with the memory system. In some examples, aspects of the operations of 605 may be performed by an offset selection component 525 as described with reference to FIG. 5.

At 610, the method may include reading, after selecting the offset table and in association with a command to read data from a block of the memory system, data from the block, where reading the data from the block includes applying an offset to a read voltage, where the offset table associates the offset with the block, and where a size of the offset is in accordance with a duration since the block was last programmed. In some examples, aspects of the operations of 610 may be performed by a read component 530 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for selecting, from among a plurality of offset tables, an offset table in accordance with a quantity of program and erase cycles associated with the memory system, where each of the plurality of offset tables indicates a respective set of offsets for read voltages associated with the memory system and reading, after selecting the offset table and in association with a command to read data from a block of the memory system, data from the block, where reading the data from the block includes applying an offset to a read voltage, where the offset table associates the offset with the block, and where a size of the offset is in accordance with a duration since the block was last programmed.

Aspect 2: The method, apparatus, or non-transitory computer-readable medium of aspect 1, further including operations, features, circuitry, logic, means, or instructions, or any combination thereof for erasing, prior to selecting the offset table, the block or a second block in the memory system; determining, in accordance with erasing the block or the second block, a second quantity of program and erase cycles for the erased block; and updating the quantity of program and erase cycles associated with the memory system to match the second quantity of program and erase cycles for the erased block.

Aspect 3: The method, apparatus, or non-transitory computer-readable medium of aspect 2, further including operations, features, circuitry, logic, means, or instructions, or any combination thereof for comparing, in accordance with determining the second quantity of program and erase cycles for the erased block, the determined second quantity of program and erase cycles with a current quantity of program and erase cycles associated with the memory system, where the quantity of program and erase cycles associated with the memory system is updated as a result of the determined second quantity of program and erase cycles being greater than the current quantity of program and erase cycles associated with the memory system.

Aspect 4: The method, apparatus, or non-transitory computer-readable medium of any of aspects 2 through 3, further including operations, features, circuitry, logic, means, or instructions, or any combination thereof for retrieving, in accordance with updating the quantity of program and erase cycles associated with the memory system, the offset table from a nonvolatile memory of the memory system, the offset table being associated with a range of program and erase cycles including the updated quantity of program and erase cycles associated with the memory system and loading, in accordance with retrieving the offset table, the offset table into a volatile memory of the memory system.

Aspect 5: The method, apparatus, or non-transitory computer-readable medium of aspect 4, further including operations, features, circuitry, logic, means, or instructions, or any combination thereof for evicting, in accordance with loading the offset table into the volatile memory, a second offset table from the volatile memory, the second offset table being associated with a second range of program and erase cycles excluding the updated quantity of program and erase cycles associated with the memory system.

Aspect 6: The method, apparatus, or non-transitory computer-readable medium of any of aspects 4 through 5, where the offset table includes a plurality of entries, respective entries of the plurality of entries including respective offsets to apply to respective blocks of the memory system in accordance with respective times since the respective blocks were programmed and the method further includes calibrating, after loading the offset table in the volatile memory, the respective offsets in accordance with a calibration schedule.

Aspect 7: The method, apparatus, or non-transitory computer-readable medium of any of aspects 2 through 6, further including operations, features, circuitry, logic, means, or instructions, or any combination thereof for selecting, prior to selecting the offset table, from among the plurality of offset tables, a second offset table in accordance with a second quantity of program and erase cycles associated with the memory system and reading, after selecting the second offset table and in association with a second command to read data from the block of the memory system, data from the block, where reading the data from the block includes applying a second offset to the read voltage, the second offset table associating the second offset with the block.

Aspect 8: The method, apparatus, or non-transitory computer-readable medium of aspect 7, further including operations, features, circuitry, logic, means, or instructions, or any combination thereof for applying the second offset to the read voltage when the block is read in association with the second command in accordance with a second time since programming the block being within a time range and applying the offset to the read voltage when the block is read in association with the command in accordance with a time since programming the block being within the time range, the time being different than the second time.

Aspect 9: The method, apparatus, or non-transitory computer-readable medium of any of aspects 2 through 8, further including operations, features, circuitry, logic, means, or instructions, or any combination thereof for configuring, prior to erasing the second block, a wear leveling task at the memory system, where the quantity of program and erase cycles associated with the memory system is updated to match the quantity of program and erase cycles for the second block in accordance with the wear leveling task being configured.

Aspect 10: The method, apparatus, or non-transitory computer-readable medium of any of aspects 1 through 9, where each of the plurality of offset tables is associated with a respective range of program and erase cycles.

Aspect 11: The method, apparatus, or non-transitory computer-readable medium of any of aspects 1 through 10, where for each offset table in the plurality of offset tables, offsets in the respective set of offsets are in accordance with respective times since respective blocks of the memory system were programmed.

Aspect 12: The method, apparatus, or non-transitory computer-readable medium of any of aspects 1 through 11, where for a first duration since the block was programmed, a first offset associated with the block in the offset table is different than a second offset associated with the block in a second offset table, wherein the offset table is associated with a first range of program and erase cycles and the second offset table is associated with a second range of program and erase cycles.

Aspect 13: The method, apparatus, or non-transitory computer-readable medium of any of aspects 1 through 12, further including operations, features, circuitry, logic, means, or instructions, or any combination thereof for receiving, after selecting the offset table, the command to read the data from the block of the memory system.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
select, from among a plurality of offset tables, an offset table in accordance with a quantity of program and erase cycles associated with the memory system, wherein each of the plurality of offset tables indicates a respective set of offsets for read voltages associated with the memory system; and
read, after selecting the offset table and in association with a command to read data from a block of the memory system, data from the block, wherein reading the data from the block comprises applying an offset to a read voltage, wherein the offset table associates the offset with the block, and wherein a size of the offset is in accordance with a duration since the block was last programmed.

2. The memory system of claim 1, wherein the processing circuitry is further configured to cause the memory system to:
erase, prior to selecting the offset table, the block or a second block in the memory system;
determine, in accordance with erasing the block or the second block, a second quantity of program and erase cycles for the erased block; and
update the quantity of program and erase cycles associated with the memory system to match the second quantity of program and erase cycles for the erased block.

3. The memory system of claim 2, wherein the processing circuitry is further configured to cause the memory system to:
compare, in accordance with determining the second quantity of program and erase cycles for the erased block, the determined second quantity of program and erase cycles with a current quantity of program and erase cycles associated with the memory system; and
update the quantity of program and erase cycles associated with the memory system as a result of the determined second quantity of program and erase cycles being greater than the current quantity of program and erase cycles associated with the memory system.

4. The memory system of claim 2, wherein the processing circuitry is further configured to cause the memory system to:
retrieve, in accordance with updating the quantity of program and erase cycles associated with the memory system, the offset table from a nonvolatile memory of the memory system, the offset table being associated with a range of program and erase cycles comprising the updated quantity of program and erase cycles associated with the memory system; and
load, in accordance with retrieving the offset table, the offset table into a volatile memory of the memory system.

5. The memory system of claim 4, wherein the processing circuitry is further configured to cause the memory system to:
evict, in accordance with loading the offset table into the volatile memory, a second offset table from the volatile memory, the second offset table being associated with a second range of program and erase cycles excluding the updated quantity of program and erase cycles associated with the memory system.

6. The memory system of claim 4, wherein:
the offset table comprises a plurality of entries, respective entries of the plurality of entries comprising respective offsets to apply to respective blocks of the memory system in accordance with respective times since the respective blocks were programmed, and
the processing circuitry is further configured to cause the memory system to calibrate, after loading the offset table in the volatile memory, the respective offsets in accordance with a calibration schedule.

7. The memory system of claim 2, wherein the processing circuitry is further configured to cause the memory system to:
select, prior to selecting the offset table, from among the plurality of offset tables, a second offset table in accordance with a second quantity of program and erase cycles associated with the memory system; and
read, after selecting the second offset table and in association with a second command to read data from the block of the memory system, data from the block, wherein reading the data from the block comprises applying a second offset to the read voltage, the second offset table associating the second offset with the block.

8. The memory system of claim 7, wherein the processing circuitry is further configured to cause the memory system to:
apply the second offset to the read voltage when the block is read in association with the second command in accordance with a second time since programming the block being within a time range, and
apply the offset to the read voltage when the block is read in association with the command in accordance with a time since programming the block being within the time range, the time being different than the second time.

9. The memory system of claim 2, wherein the processing circuitry is further configured to cause the memory system to:
configure, prior to erasing the second block, a wear leveling task at the memory system, wherein the quantity of program and erase cycles associated with the memory system is updated to match the quantity of program and erase cycles for the second block in accordance with the wear leveling task being configured.

10. The memory system of claim 1, wherein each of the plurality of offset tables is associated with a respective range of program and erase cycles.

11. The memory system of claim 1, wherein, for each offset table in the plurality of offset tables, offsets in the respective set of offsets are in accordance with respective times since respective blocks of the memory system were programmed.

12. The memory system of claim 1, wherein, for a first duration since the block was programmed, a first offset associated with the block in the offset table is different than a second offset associated with the block in a second offset table, wherein the offset table is associated with a first range of program and erase cycles, and wherein the second offset table is associated with a second range of program and erase cycles.

13. The memory system of claim 1, wherein the processing circuitry is further configured to cause the memory system to:
receive, after selecting the offset table, the command to read the data from the block of the memory system.

14. A non-transitory, computer-readable medium storing code comprising instructions executable by processing circuitry of a memory system to cause the memory system to:
select, from among a plurality of offset tables, an offset table in accordance with a quantity of program and erase cycles associated with the memory system, wherein each of the plurality of offset tables indicates a respective set of offsets for read voltages associated with the memory system; and
read, after selecting the offset table and in association with a command to read data from a block of the memory system, data from the block, wherein reading the data from the block comprises applying an offset to a read voltage, wherein the offset table associates the offset with the block, and wherein a size of the offset is in accordance with a duration since the block was last programmed.

15. The non-transitory, computer-readable medium of claim 14, wherein the instructions are further exectuable by the processing circuitry to cause the memory system to:
erase, prior to selecting the offset table, the block or a second block in the memory system;
determine, in accordance with erasing the block or the second block, a second quantity of program and erase cycles for the erased block; and
update the quantity of program and erase cycles associated with the memory system to match the second quantity of program and erase cycles for the erased block.

16. The non-transitory, computer-readable medium of claim 15, wherein the instructions are further exectuable by the processing circuitry to cause the memory system to:
compare, in accordance with determining the second quantity of program and erase cycles for the erased block, the determined second quantity of program and erase cycles with a current quantity of program and erase cycles associated with the memory system; and
update the quantity of program and erase cycles associated with the memory system as a result of the determined second quantity of program and erase cycles being greater than the current quantity of program and erase cycles associated with the memory system.

17. The non-transitory, computer-readable medium of claim 15, wherein the processing circuitry is further configured to cause the memory system to:
retrieve, in accordance with updating the quantity of program and erase cycles associated with the memory system, the offset table from a nonvolatile memory of the memory system, the offset table being associated with a range of program and erase cycles comprising the updated quantity of program and erase cycles associated with the memory system; and
load, in accordance with retrieving the offset table, the offset table into a volatile memory of the memory system.

18. The non-transitory, computer-readable medium of claim 15, wherein the processing circuitry is further configured to cause the memory system to:
select, prior to selecting the offset table, from among the plurality of offset tables, a second offset table in accordance with a second quantity of program and erase cycles associated with the memory system; and
read, after selecting the second offset table and in association with a second command to read data from the block of the memory system, data from the block, wherein reading the data from the block comprises applying a second offset to the read voltage, the second offset table associating the second offset with the block.

19. The non-transitory, computer-readable medium of claim 15, wherein the processing circuitry is further configured to cause the memory system to:
configure, prior to erasing the second block, a wear leveling task at the memory system, wherein the quantity of program and erase cycles associated with the memory system is updated to match the quantity of program and erase cycles for the second block in accordance with the wear leveling task being configured.

20. A method at a memory system, comprising:
selecting, from among a plurality of offset tables, an offset table in accordance with a quantity of program and erase cycles associated with the memory system, wherein each of the plurality of offset tables indicates a respective set of offsets for read voltages associated with the memory system; and
reading, after selecting the offset table and in association with a command to read data from a block of the memory system, data from the block, wherein reading the data from the block comprises applying an offset to a read voltage, wherein the offset table associates the offset with the block, and wherein a size of the offset is in accordance with a duration since the block was last programmed.

21. The method of claim 20, further comprising:
erasing, prior to selecting the offset table, the block or a second block in the memory system;
determining, in accordance with erasing the block or the second block, a second quantity of program and erase cycles for the erased block; and
updating the quantity of program and erase cycles associated with the memory system to match the second quantity of program and erase cycles for the erased block.

22. The method of claim 21, further comprising:
comparing, in accordance with determining the second quantity of program and erase cycles for the erased block, the determined second quantity of program and erase cycles with a current quantity of program and erase cycles associated with the memory system; and
updating the quantity of program and erase cycles associated with the memory system as a result of the determined second quantity of program and erase cycles being greater than the current quantity of program and erase cycles associated with the memory system.

23. The method of claim 21, further comprising:
retrieving, in accordance with updating the quantity of program and erase cycles associated with the memory system, the offset table from a nonvolatile memory of the memory system, the offset table being associated with a range of program and erase cycles comprising the updated quantity of program and erase cycles associated with the memory system; and
loading, in accordance with retrieving the offset table, the offset table into a volatile memory of the memory system.

24. The method of claim 21, further comprising:
selecting, prior to selecting the offset table, from among the plurality of offset tables, a second offset table in accordance with a second quantity of program and erase cycles associated with the memory system; and
reading, after selecting the second offset table and in association with a second command to read data from the block of the memory system, data from the block, wherein reading the data from the block comprises applying a second offset to the read voltage, the second offset table associating the second offset with the block.

25. The method of claim 21, further comprising:
configuring, prior to erasing the second block, a wear leveling task at the memory system, wherein the quantity of program and erase cycles associated with the memory system is updated to match the quantity of program and erase cycles for the second block in accordance with the wear leveling task being configured.
